(19) United States
(12) Patent Application Publication
(10) Pub. No.: US 2013/0344637 A1
(43) Pub. Date: Dec. 26, 2013

(54) MASK FOR MANUFACTURING DOPANT LAYER OF SOLAR CELL, METHOD FOR MANUFACTURING DOPANT LAYER OF SOLAR CELL, AND METHOD FOR MANUFACTURING DOPANT LAYER OF SOLAR CELL USING THE MASK

(71) Applicant: LG Electronics Inc., Seoul (KR)

(72) Inventors: Jinsung KIM, Seoul (KR); Chunghyun LIM, Seoul (KR)

(21) Appl. No.: 13/924,257

(22) Filed: Jun. 21, 2013

(30) Foreign Application Priority Data
Jun. 22, 2012 (KR) 10-2012-0067538

(51) Int. Cl. H01L 31/18

(52) U.S. Cl. CPC H01L 31/18
USPC 438/57; 264/400; 118/213

(57) ABSTRACT

Discussed is a method for manufacturing a mask for a solar cell according to an embodiment, the method including preparing a plate formed of a nonmetallic material, and irradiating the plate with a laser and forming a plurality of slits.

### CROSS-REFERENCE TO RELATED APPLICATION

This application claims the priority benefit of Korean Patent Application No. 10-2012-0067538, filed on Jun. 22, 2012 in the Korean Intellectual Property Office, the disclosure of which is incorporated herein by reference.

### BACKGROUND OF THE INVENTION

1. Field of the Invention

Embodiments of the present invention relate to a mask for formation of a dopant layer for a solar cell and method for manufacturing the same, and a method for manufacturing a dopant layer for the solar cell using the same.

2. Description of the Related Art

As conventional energy sources such as petroleum and coal are being depleted, alternative energy sources have become a focus of attention as replacements. Among alternative energy sources, solar cells, which can convert solar energy into electric energy, have become a major area of interest as next generation cells are being developed.

The solar cell includes a p-n junction formed by forming dopant layers to perform photoelectric transformation, and an electrode connected to an n-type dopant layer and/or a p-type dopant layer. To enhance the properties of such dopant layers, variation in the amount of a dopant introduced into the dopant layers has been proposed. To form dopant layers having such a structure, a mask having a plurality of slits is used. However, manufacturing the slits having a very small width and a tiny gap therebetween is difficult and productivity thereof is low.

### SUMMARY OF THE INVENTION

Therefore, embodiments of the present invention have been made in view of the above problems, and it is an object of the present invention to provide a proper mask for a solar cell by forming dopant layers for the solar cell having a very small width and a tiny gap therebetween.

It is another object of the present invention to provide a method for manufacturing the mask with high productivity and a method of manufacturing a dopant layer for a solar cell using the same.

In accordance with an aspect of the present invention, the above and other objects can be accomplished by the provision of a method for manufacturing a mask for a solar cell, the method including preparing a plate formed of a nonmetallic material, and irradiating the plate with a laser and forming a plurality of slits.

A width of each of the plurality of slits may be between about 0.1 mm and about 0.4 mm, and a distance between neighboring ones of the plurality of slits may be between about 0.6 mm and about 1 mm.

In accordance with another aspect of the present invention, there is provided a method for manufacturing a dopant layer for a solar cell, the method including preparing a semiconductor substrate, positioning a mask on the semiconductor substrate, and doping the semiconductor substrate with a dopant and forming a dopant layer having a selective structure or a local structure, wherein the mask includes a plurality of slits formed by irradiating a plate formed of a nonmetallic material with a laser.

### BRIEF DESCRIPTION OF THE DRAWINGS

The above and other objects, features and other advantages of the embodiments of the present invention will be more clearly understood from the following detailed description taken in conjunction with the accompanying drawings, in which:

FIG. 1 is a cross-sectional view showing an example of a solar cell manufactured using a method for manufacturing a solar cell according to an example embodiment of the present invention;

FIG. 2 is a plan view showing the solar cell of FIG. 1;

FIG. 3 is a plan view showing a mask according an embodiment of the present invention;

FIGS. 4A and 4B are perspective views illustrating a method for manufacturing a mask according to one embodiment of the present invention;

FIG. 5 is a plan view showing a mask according to another embodiment of the present invention;

FIG. 6 is a plan view showing a mask according to another embodiment of the present invention;

FIG. 7 is a flowchart illustrating a method for manufacturing a solar cell according to an embodiment of the present invention;

FIGS. 8A to 8G are a flowchart illustrating the method for manufacturing a solar cell according to the embodiment of the present invention;

FIG. 9 is a cross-sectional view showing another example of a solar cell manufactured via a method for manufacturing a solar cell according to one embodiment of the present invention;

FIG. 10 is a photo of slits manufactured according to Experiment 1; and

FIG. 11 is a photo of slits manufactured according to Experiment 2.

### DETAILED DESCRIPTION OF THE EMBODIMENTS

Reference will now be made in detail to the embodiments of the present invention, examples of which are illustrated in the accompanying drawings.

For clear and brief description of the present invention, parts irrelevant to the description are omitted in the drawings. Wherever possible, the same reference numbers will be used throughout the drawings to refer to the same or like parts. In addition, for clear illustration, thickness and areas are enlarged or reduced in the drawings. Thickness and areas of the present invention are not limited to what is shown the drawings.

In addition, when it is stated in this specification that a part “includes” a portion, it does not mean that the part excludes other portions, but that the part may further include other portions, unless stated otherwise. In addition, when it is stated that a portion such as a layer, a film, a region, or a plate is “on” another portion, it includes not only the case of having the other portion “directly on” the portion but also the case of intervening portions therebetween. When it is stated that a portion such as a layer, a film, a region, or a plate is “directly on” another portion, it means that the two portions have nothing positioned therebetween.

An example of a solar cell manufactured via a method for manufacturing a solar cell according to an embodiment of the present invention will be described first and then a method for manufacturing a dopant layer of the solar cell using a mask and a method for manufacturing a solar cell including the dopant layer will be described.

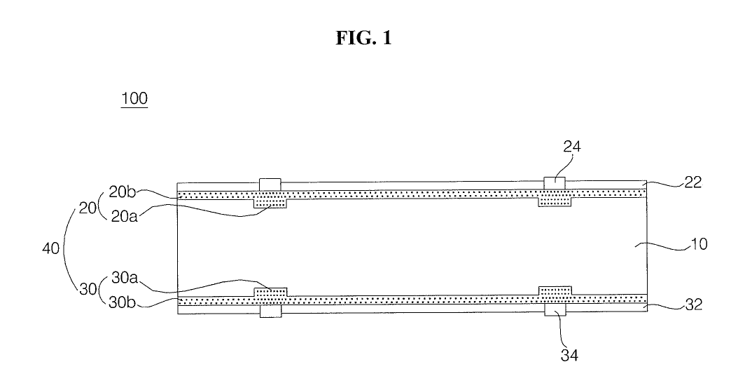

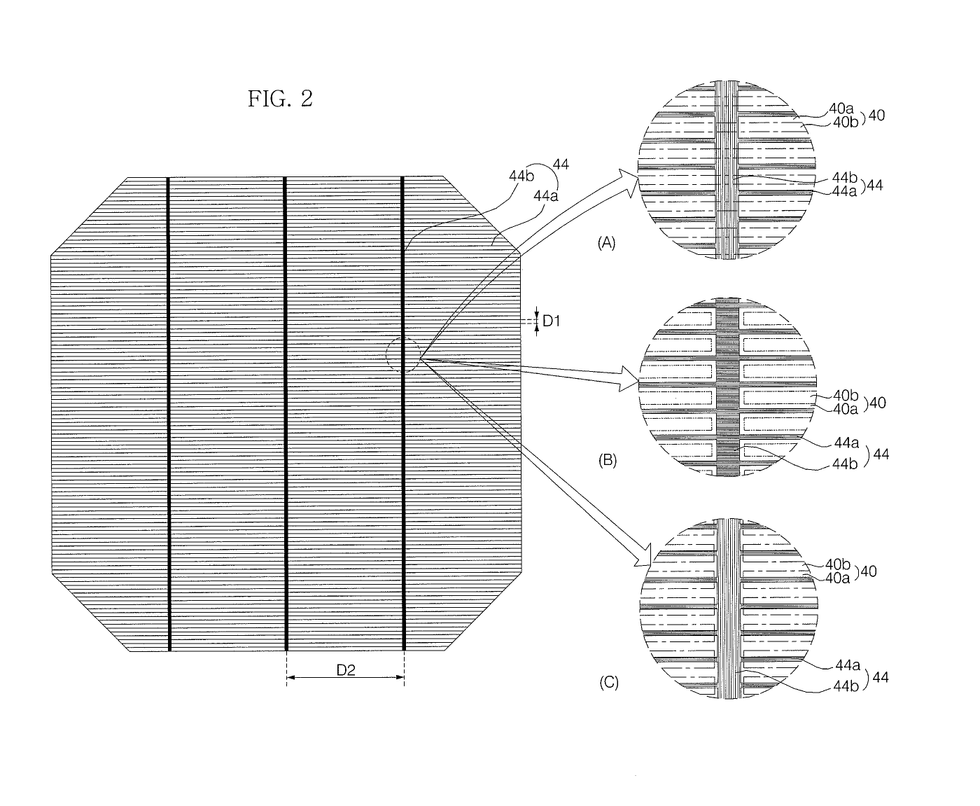

FIG. 1 is a cross-sectional view showing an example of a solar cell manufactured via a method for manufacturing a solar cell according to an example embodiment of the present invention, and FIG. 2 is a plan view showing the solar cell of FIG. 1.

Referring to FIG. 1, a solar cell 100 may include a semiconductor substrate 10, an emitter layer 20 positioned on a first surface (hereinafter, “front surface”) of the semiconductor substrate 10 and provided with a first conductive dopant, a back surface field layer 30 positioned on a second surface (hereinafter, “back surface”) of the semiconductor substrate 10 and provided with a second conductive dopant, an anti-reflective film 22 and a first electrode 24 formed on the front surface of the semiconductor substrate 10, and a passivation film 32 and a second electrode 34 positioned on the semiconductor substrate 10. A description thereof is given below in more detail.

The semiconductor substrate 10 may include various semiconductor materials. For example, it may include silicon including the second conductive dopant. As the silicon, single crystal silicon or polycrystalline silicon can be used. An example of the second conductive dopant is an n-type dopant. That is, the semiconductor substrate 10 may be formed of single crystal silicon or polycrystalline silicon doped with a Group V element such as phosphorus (P), arsenic (As), bismuth (Bi), antimony (Sb), etc.

When the semiconductor substrate 10 having an n-type dopant is used, the emitter layer 20 having a p-type dopant is formed on the front surface of the semiconductor substrate 10 and thereby a p-n junction is formed. When the p-n junction is irradiated with light, electrons produced according to the photoelectric effect are moved to the back surface of the semiconductor substrate 10 and collected by the second electrode 34, while holes are moved to the front surface of the semiconductor substrate 10 and collected by the first electrode 24. Thereby, electric energy is generated.

Here, the holes, which move slower than the electrons, move to the front surface of the semiconductor substrate 10, not to the back surface thereof, and therefore photoelectric transformation efficiency may be improved.

Although not shown, the front surface of the semiconductor substrate 10 is textured to be an uneven surface in a shape, e.g., a pyramidal shape. By forming the front surface of the semiconductor substrate 10 to be uneven, thereby increasing roughness thereof through texturing, reflectivity of light incident on the front surface of the semiconductor substrate 10 can be reduced. Accordingly, the amount of light reaching the p-n junction formed at the interface between the semiconductor substrate 10 and the emitter layer 20 can be increased and thus loss of light can be minimized. The back surface of the semiconductor substrate 10 is not textured and thus can have lower roughness than the front surface. This is because etching is performed on the back surface of the semiconductor substrate 10 after texturing of the semiconductor substrate 10, which will be described later in more detail.

The emitter layer 20 having the first conductive dopant may be formed on the front surface of the semiconductor substrate 10. In the illustrated embodiment, the emitter layer 20 may use p-type dopants such as boron (B), aluminum (Al), gallium (Ga) and indium (In), which are Group III elements, as the first conductive dopant.

In the illustrated embodiment, the emitter layer 20 includes a first portion 20a having a high dopant concentration and thereby a relatively low resistance, and a second portion 20b having a dopant concentration lower than that of the first portion 20a and thereby a relatively high resistance. The first portion 20a is formed to contact part of (i.e., at least one part of) or the entirety of the first electrode 24.

In the illustrated embodiment, by forming the second portion 20b with a relatively high resistance at a corresponding portion of the first electrode 24 upon which light is incident, a shallow emitter is realized. Thereby, current density of the solar cell 100 can be enhanced. In addition, by forming the first portion 20a with a relatively low resistance at a portion adjacent to the first electrode 24, contact resistance with the first electrode 24 can be reduced. That is, the emitter layer 20 of the illustrated embodiment can maximize the efficiency of the solar cell 100 through the selective emitter structure.

The anti-reflective film 22 and the first electrode 24 are formed on the emitter layer 20 on the front surface of the semiconductor substrate 10.

The anti-reflective film 22 may be formed on substantially the entire front surface of the semiconductor substrate 10 except the portions at which the first electrode 24 is formed. The anti-reflective film 22 lowers reflectivity of light incident on the front surface of the semiconductor substrate 10, and passivates defects present on the surface of the emitter layer 20 or in the bulk of the emitter layer 20.

By lowering reflectivity of light incident on the front surface of the semiconductor substrate 10, the amount of light reaching the p-n junction formed at the interface between the semiconductor substrate 10 and the emitter layer 20 can be increased. Thereby, short-circuit current Isc of the solar cell 100 can be increased. In addition, by eliminating sites of recombination of minority carriers through passivation of the defects present in the emitter layer 20, open-circuit voltage Voc of the solar cell 100 can be increased. By increasing the open-circuit voltage and short-circuit current of the solar cell 100 by means of the anti-reflective film 22 as above, efficiency of the solar cell 100 can be enhanced.

The anti-reflective film 22 can be formed of various materials. For example, the anti-reflective film 22 may have a single film selected from a group including a silicon nitride film, a silicon nitride film including hydrogen, a silicon dioxide film, a silicon oxynitride film, an aluminum oxide film, MgF2, ZnS, TiO2 and CeO2 or have a multi-layer film structure formed by combination of two or more films from the group. However, embodiments of the present invention are not limited thereto. The anti-reflective film 22 can include various materials.

At least one part of the first electrode 24 can be electrically connected to the emitter layer 20 through the anti-reflective film 22 on the front surface of the semiconductor substrate 10. The first electrode 24 may include various metals having good electrical conductivity. For example, the first electrode 24 may include silver (Ag) having good electrical conductivity.

Formed on the back surface of the semiconductor substrate 10 is the back surface field layer 30, which includes the second conductive dopant whose doping concentration is higher than that of the semiconductor substrate 10.

A back surface field layer 30 having the second conductive dopant can be formed on the back surface of the semiconductor substrate 10. In the illustrated embodiment, the back surface field layer 30 can be doped with n-type dopants such as phosphorus (P), arsenic (As), bismuth (Bi), antimony (Sb), which are Group V elements, as the second conductive dopant.

In the illustrated embodiment, the back surface field layer 30 may have a first portion 30a having a high dopant concentration and thereby a relatively low resistance, and a second portion 30b having a dopant concentration lower than that of the first portion 30a and thereby a relatively high resistance. The first portion 30a is formed to contact part of or (i.e., at least one part of) the entire second electrode 34.

In the illustrated embodiment, by forming the second portion 30b with a relatively high resistance at a corresponding portion of the second electrode 34 as above, recombination between holes and electrons can be prevented. Thereby, current density of the solar cell 100 can be enhanced. In addition, by forming the first portion 30a with a relatively low resistance at a portion adjacent to the second electrode 34, contact resistance with the second electrode 34 can be reduced. That is, the back surface field layer 30 of the illustrated embodiment can maximize the efficiency of the solar cell 100 through the selective back surface electric field structure.

In addition, the passivation film 32 and the second electrode 34 may be formed on the back surface of the semiconductor substrate 10.

The passivation film 32 may be formed on substantially the entire back surface of the semiconductor substrate 10 except the portions at which the second electrode 34 is formed. The passivation film 32 can eliminate sites of recombination of minority carriers by passivating defects present on the back surface of the semiconductor substrate 10. Thereby, open-circuit voltage Voc of the solar cell 100 can be increased.

The passivation film 32 may be formed of a transparent insulation material allowing light to be transmitted therethrough. Accordingly, by allowing light to be incident on the back surface of the semiconductor substrate 10 through the passivation film 32, efficiency of the solar cell 100 can be improved. For example, the passivation film 32 may have a single film selected from a group including a silicon nitride film, a silicon nitride film including hydrogen, a silicon dioxide film, a silicon oxynitride film, an aluminum oxide film, MgF2, ZnS, TiO2 and CeO2 or have a multi-layer film structure formed by combination of two or more films from the group. However, embodiments of the present invention are not limited thereto. The passivation film 32 can include various materials.

The second electrode 34 may include various metals having good electrical conductivity. For example, the second electrode 34 may include silver (Ag) having good electrical conductivity and high reflectivity. When silver having high reflectivity is used as the second electrode 34, light traveling out of the back surface of the semiconductor substrate 10 can be reflected and directed back into the semiconductor substrate 10, and thereby the amount of light used can be increased.

The second electrode 34 as above may be formed to have a larger width than the first electrode 24.

The first electrode 24 and/or the second electrode (hereinafter, referred to as “electrode 44”) having a planar shape will be described below in more detail with reference to FIG. 2. In the illustrated embodiment, the electrode 44 can have various planar shapes. Thereby, the first portion 20a or 30a (hereinafter, referred to as “first portion 40a”) formed to contact at least one part of the electrode 44, and other portion of the second portion 20b or 30b (hereinafter, referred to as “second portion 40b”), which indicates the other portion, may also have various shapes.

For example, as shown in FIG. 2, the electrode 44 may include finger electrodes 44a spaced a first distance D1 from each other and disposed parallel to each other. In addition, the electrode 44 may include bus bar electrodes 44b formed in a direction crossing the finger electrodes 44a to connect the finger electrodes 44a to each other. One bus electrode 44b may be provided, or a plurality of bus electrodes 44b may be arranged to be spaced a second distance D2 longer than the first distance D1 from each other, as shown in FIG. 2. Here, the bus bar electrodes 44b may have a larger width than the finger electrode 44a. However, embodiments of the present invention are not limited thereto. Both may have the same width. The shape of the electrodes 44 described above is simply illustrative, and embodiments of the present invention are not limited thereto.

The finger electrode 44a and the bus bar electrodes 44b may both be formed to penetrate through the anti-reflective film 22 or the passivation film 32. The electrodes 44 having this structure can be formed by fire-through. For example, a paste capable of causing fire through may be formed on the anti-reflective film 22 or the passivation film 32 to have the shapes of the finger electrodes 44a and the bus bar electrodes 44b and treated with heat to form the electrode 44 to contact the emitter layer 20 or the back surface field layer 30 (hereinafter, referred to as “dopant layer 40”).

Alternatively, the finger electrodes 44a may be formed through the anti-reflective film 22 or the passivation film 32, and the bus bar electrodes 44b may be formed on the anti-reflective film 22 or the passivation film 32. The electrode 44 having this structure can be manufactured in the following manner. First, a paste allowing fire through to occur is formed on the anti-reflective film 22 or the passivation film 32 to have the shape of the finger electrodes 44a. Next, the paste is treated with heat to cause fire through such that the paste moves through the anti-reflective film 22 or the passivation film 32, allowing at least one part of the finger electrodes 44a to contact the dopant layer 40. Then, the bus bar electrodes 44b to connect the finger electrodes 44a to each other are formed on the anti-reflective film 22 or the passivation film 32.

However, embodiments of the present invention are not limited thereto. The electrode 44 can be formed by forming openings in the anti-reflective film 22 or the passivation film 32 and performing such operations as coating and deposition.

At this time, as shown in (A) of FIG. 2, the first portion 40a may be formed to extend by connecting the portions corresponding to the finger electrodes 44a to each other. Alternatively, as shown in (B) of FIG. 2, the first portion 40a may be formed to correspond to the finger electrode 44a and the bus bar electrodes 44b. Alternatively, as shown in (C) of FIG. 2, the first portion 40a may be spaced apart from the portions at which the bus bar electrodes 44b are formed and may correspond to the finger electrodes 44a.

In the illustrated embodiment, the dopant layer 40 having selective structures as above is formed using a mask. Hereinafter, a mask used in forming the dopant layer 40 and a method for manufacturing the mask will be described, and then a method for forming the dopant layer 40 using the mask and a method for manufacturing the solar cell 100 including the dopant layer 40 will be described.

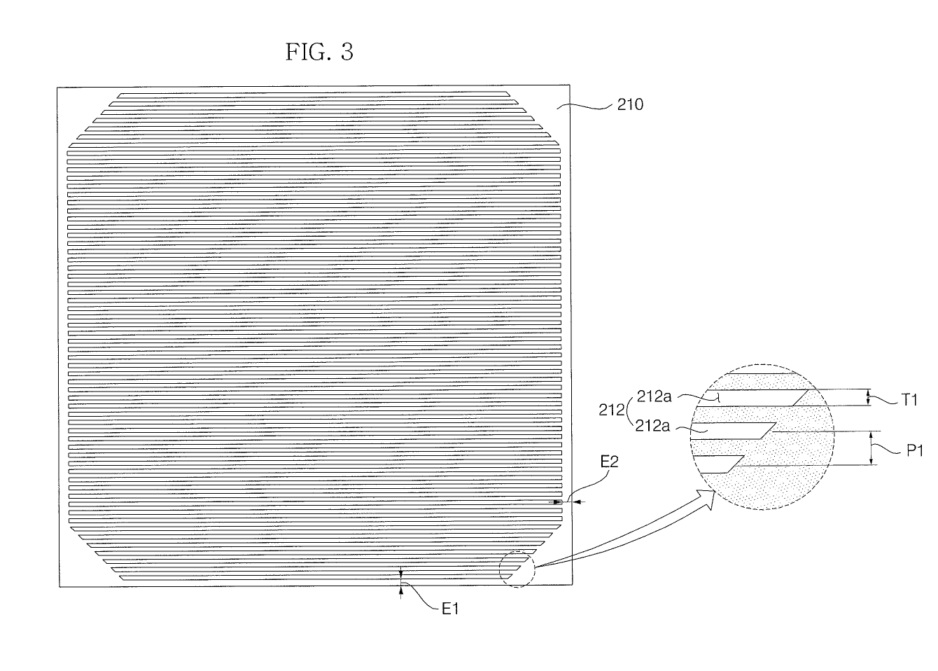

FIG. 3 is a plan view showing a mask according an embodiment of the present invention.

Referring to FIG. 3, the mask 210 according to the illustrated embodiment is provided with a plurality of slits 212 to expose portions corresponding to the first portion (reference numeral 40a in FIG. 2) having a relatively high doping concentration and a low resistance.

More specifically, in the illustrated embodiment, each of the slits 212 may include a first slit portion 212a formed to correspond to the finger electrode 44a. The first slit portion 212a may extend endlessly from the mask 210 in one direction. The first slit portions 212a may be disposed parallel to each other. The first slit portions 212a may be formed to have a width T1 corresponding to that of the finger electrode 44a and to be spaced a pitch P1 from each other in consideration of tolerance.

For example, the width T1 of the first slit portion 212a may be between 0.1 mm and 0.4 mm (more specifically, between 0.2 mm and 0.35 mm). In addition, the pitch P1 of neighboring ones of the first slit portions 212a is equal to or less than 1 mm (more specifically, between 0.6 mm and 1 mm). In the illustrated embodiment, the width T1 of the first slit portions 212a and the pitch P1 thereof may be reduced since a laser is used to form the first slit portions 212a. This will be described later in more detail.

In the illustrated embodiment, the width of the first portion 40a can be reduced by reducing the width T1 of the first slit portion 212a, and therefore formation of the first portion 40 at an unnecessary position can be prevented. In addition, the pitch P1 of the first slit portions 212a can be reduced, and thus the distance between the first portions 40a can be reduced. Thereby, the distance between the finger electrodes 44a can be reduced. That is, current produced by photoelectric transformation can be effectively collected by densely forming the finger electrodes 44a. As a result, efficiency of the solar cell 100 can be enhanced.

The distance E1 between the outermost first slit portion 212a and the edge of the mask 210 may be between about 0.8 mm and about 1.2 mm. The distance E2 between an end the first slit portion 212a and the edge of the mask 210 may be between about 0.8 mm and about 1.2 mm. In the case that the distances E1 and E2 are less than 0.8 mm, the edge portion of the mask 210 may be damaged and the portion corresponding to the first slit portion 212a may be cleanly removed. In the case that the distances E1 and E2 are greater than 1.2 mm, the margin may be unnecessarily increased.

Embodiments of the present invention are not limited thereto. The width of the first slit portion 212a, the space between the first slit portions 212a and the distance to the edge may vary.

The mask 210 of the illustrated embodiment can be used to form the first portions 40a in the shape as shown in (B) of FIG. 2.

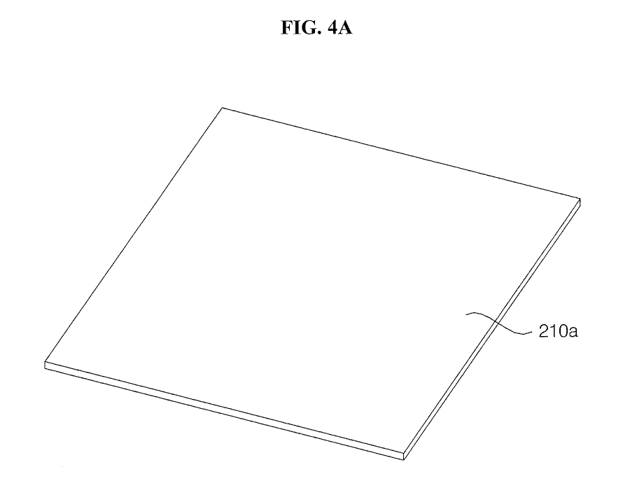

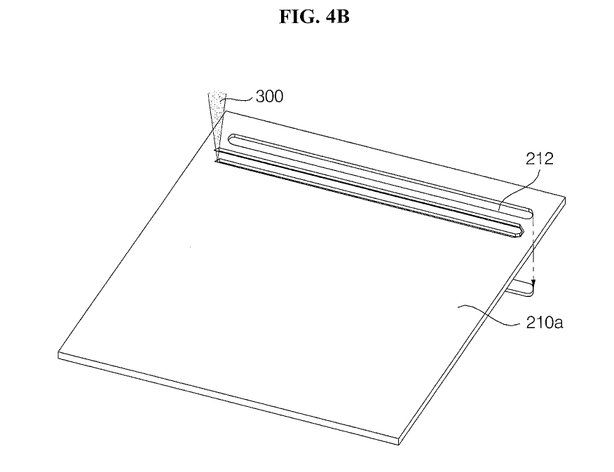

A method for manufacturing such a mask 210 will be described with reference to FIGS. 4A and 4B. FIGS. 4A and 4B are perspective views illustrating a method for manufacturing a mask according to one embodiment of the present invention.

As shown in FIG. 4A, a plate 210a needed to manufacture a mask is prepared. In the illustrated embodiment, the plate 210a may include various materials that prevent contamination of the solar cell 100 while the solar cell 100 is being manufactured. That is, the plate 210a may be formed of a nonmetallic material that does not affect the electrical properties of the solar cell 100. For example, the plate 210a may include graphite. The plate 210a can be manufactured using various techniques, and may have a thickness between 0.8 mm and 1.2 mm. In the case that the thickness of the plate 210a exceeds 1.2 mm, it may be difficult to form slits (reference numeral 212 in FIG. 4B) in the plate 210a. In the case that the thickness of the plate 210a is less than 0.8 mm, the plate 210a may have low mechanical strength, and thereby it may be deflected during a process.

Before slits 212 are formed, the prepared plate 210a may be treated with heat to eliminate contaminants. For example, contaminants may be eliminated by exposing the plate 210a to a heat treatment between about 500° C. and about 900° C. for between about 30 minutes and about 10 hours under a nitrogen atmosphere in a furnace.

Subsequently, the plate 210a is irradiated with a laser 300 to form a plurality of slits 212, as shown in FIG. 4B. More specifically, when the laser 300 is emitted to the plate 210a along the boundary of each of the slits 212, the portion irradiated with the laser 300 melts. When the entire boundary of a slit 212 is irradiated with the laser 300 to form a closed curve, the portion within the closed curve is separated from the plate 210a. Thereby, the slits 212 are formed in the plate 210a.

As the laser 300, a high power laser, which can melt the plate 210a, thus forming the slits 212, can be used. For example, a femtosecond laser or a picosecond laser can be used as the laser 300. The wavelength, frequency and power of the laser 300 can be changed in consideration of thickness of the plate 210a, shape of the slits 212, and processing time.

For example, a picosecond laser having a wavelength between about 300 nm and about 800 nm (e.g., between about 300 nm and 500 nm), a frequency between about 100 kHz and about 400 kHz, and a power between 30 W and 50 W can be used as the laser 300. Within these ranges of wavelength, frequency, and power, the plate 210a can be easily processed using the laser 300 and setting the laser equipment is facilitated. In the case that the frequency exceeds 400 kHz, the equipment may be difficult to set. In the case that the frequency is less than 100 kHz, processing using the laser 300 may require an excessively long time. In addition, in the case that the power exceeds 50 W, setting the laser equipment may be difficult. In the case that the power is lower than 30 W, processing with the laser 300 may take a long time.

In conventional cases, the plate is mechanically machined to form slits to manufacture a mask used in various fields. Mechanical machining of the plate including a metallic material is easy. However, in the case that the mask is formed of a nonmetallic material (e.g., graphite) to prevent contamination by foreign substances during the process of manufacturing the solar cell, as in the illustrated embodiment, forming the slits through mechanical machining is difficult. That is, a nonmetallic material has brittleness and thus can be easily broken if mechanically machined.

On the other hand, in the illustrated embodiment the slits 212 are formed in the plate 210a including a nonmetallic material using the laser 300, and therefore the plate 210a can be formed in a desired shape without damage. In addition, by limiting the ranges of wavelength, frequency and power of the laser 300 to suit machining of the plate 210a including a nonmetallic material (e.g., graphite), time taken to manufacture the mask 210 can be reduced, and yield rate can be increased. For example, in the case that the laser 300 is a picoseconds laser having a wavelength between about 300 and about 800 nm (e.g., between about 300 nm and about 500 nm), frequency between about 100 kHz and about 400 KHz, and power between about 30 W and about 50 W, one mask 210 can be manufactured within two days. In this case, the yield rate is over 50%.

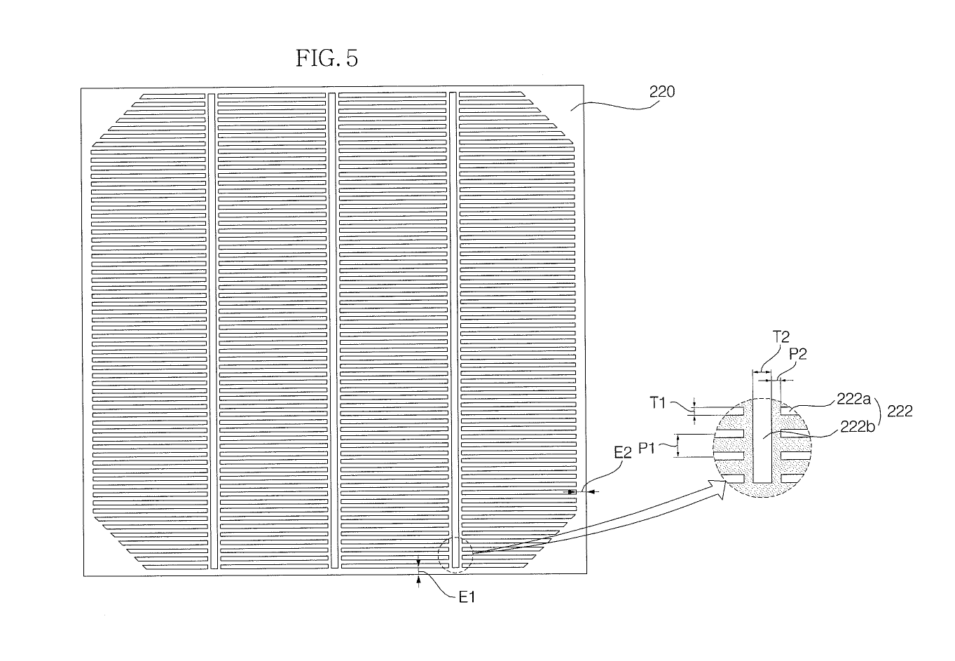

Hereinafter, a mask according to another embodiment will be described with reference to FIGS. 5 and 6. A description of constituents identical or similar to those of the mask in the previous embodiment will be omitted, and different constituents will be focused upon.

FIG. 5 is a plan view showing a mask according to another embodiment of the present invention.

Referring to FIG. 5, a plurality of slits 222 of a mask 220 according to the illustrated embodiment includes a first slit portion 222a formed in a first direction to correspond to the finger electrode 44a, and a second slit portion 222b formed in a direction crossing the first direction to correspond to the bus bar electrode 44b.

For example, the width T1 of the first slit portion 222a may be between about 0.1 mm and about 0.4 mm (more specifically, between about 0.2 mm and about 0.35 mm). The pitch P1 of the first slit portions 222a may be equal to or less than 1 mm (more specifically, between about 0.6 mm and about 1 mm). The distance E1 between the outermost first slit portion 222a and the edge of the mask 210 may be between about 0.8 mm and about 1.2 m, and the distance E2 between an end of the first slit portion 222a and the edge of the mask 210 may be between about 0.8 mm and about 1.2 mm. The width T2 of the second slit portion 222b may be between about 1 mm and about 3 mm.

In addition, the first slit portion 222a and the second slit portion 222b may be spaced a predetermined distance P2 apart from each other. In the case that the first slit portion 222a is connected to the second slit portion 222b, the strength of the mask 220 may be lowered. Further, as the space between the neighboring first and/or second slit portions 222a and 222b is eliminated, it is not possible to manufacture a mask 220 having a desired shape.

For example, the distance P2 between the first slit portion 222a and the second slit portion 222b may be about 0.5 mm and about 2 mm. In the case that the distance P2 exceeds 2 mm, the distance between the first portion 40a formed by the first slit portion 222a and the second portion 40b formed by the second slit portion 222b grows, and thereby the area of the portion having higher contact resistance with the electrode 44 may increase. In the case that the distance P2 is less than 0.5 mm, the first slit portion 222a and the second slit portion 222b are positioned too close to each other, and thereby the same portion may be weakened and thus damaged.

Embodiments of the present invention are not limited thereto. The width of the first slit portion 222a and the second slit portion 222b, the distance therebetween and the distance to the edge of the mask may vary.

The mask 220 of the illustrated embodiment can be used to form the first portions 40a as shown in (B) of FIG. 2. Thereby, contact resistance with the electrode 44 can be minimized by allowing the first portions 40b to contact the entire finger electrode 44a and bus bar electrodes 44b.

FIG. 6 is a plan view showing a mask according to another embodiment of the present invention.

Referring to FIG. 6, a plurality of slits 232 of a mask 230 according to the illustrated embodiment includes a first slit portion 232a formed in the first direction to correspond to the finger electrode 44a. The first slit portion 232a may not be formed at a position at which the bus bar electrode 44b will be formed. In this case, the first slit portion 232a may include a plurality of slit portions arranged in the first direction and spaced from each other, the portion corresponding to the bus bar electrode 44b being placed between the slit portions.

For example, the width T1 of the first slit portion 232a may be between about 0.1 mm and about 0.4 mm (more specifically, between about 0.2 mm and about 0.35 mm). The distance P1 between the first slit portions 232a in the direction crossing the first slit portions 232a may be equal to or less than 1 mm (more specifically, between about 0.6 mm and about 1 mm).

The first slit portions 232a (more specifically, a plurality of slit portions) may be positioned to be spaced a predetermined distance P3 from each other in the direction parallel to the first slit portion 232a. Thereby, each of the first slit portions 232a can be formed to have a short length to prevent the portion between the first slit portions 232a from being deflected. That is, in the case that the first slit portions 212a are formed on the entire mask 210 as shown in FIG. 3, the first slit portions 212a are elongated, and thereby the portion between the first slit portions 212a may be deflected downward. Accordingly, in the illustrated embodiment, by shortening the first slit portion 232a, the mechanical strength of the mask 230 can be enhanced.

For example, the distance P3 between the first slit portions 232a in the direction parallel to the first slit portion 232a may be between about 1 mm and about 2 mm. In the case that the distance P3 exceeds 2 mm, the margin may unnecessarily increase. In the case that the distance P3 is less than 0.5 mm, the distance between the first slit portions 232a is not sufficient, and thereby the distance P3 may not be sufficient.

The distance E1 between the outermost first slit portion 232a and the edge of the mask 230 may be between about 0.8 mm and about 1.2 m, and the distance E2 between an end the outermost first slit portion 232a and the edge of the mask 230 may be between about 0.8 mm and about 1.2 mm.

However, embodiments of the present invention are not limited thereto. The width of the first slit portions 232a, the distance therebetween, and the distance to the edge of the mask may vary.

The mask 230 of the illustrated embodiment can be used to form the first portions 40a as shown in (C) of FIG. 2.

Hereinafter, a method for manufacturing a dopant layer for a solar cell using the mask 210, 220, 230 (hereinafter, referred to as “mask 200”) and a method for manufacturing the solar cell including the dopant layer will be described in detail.

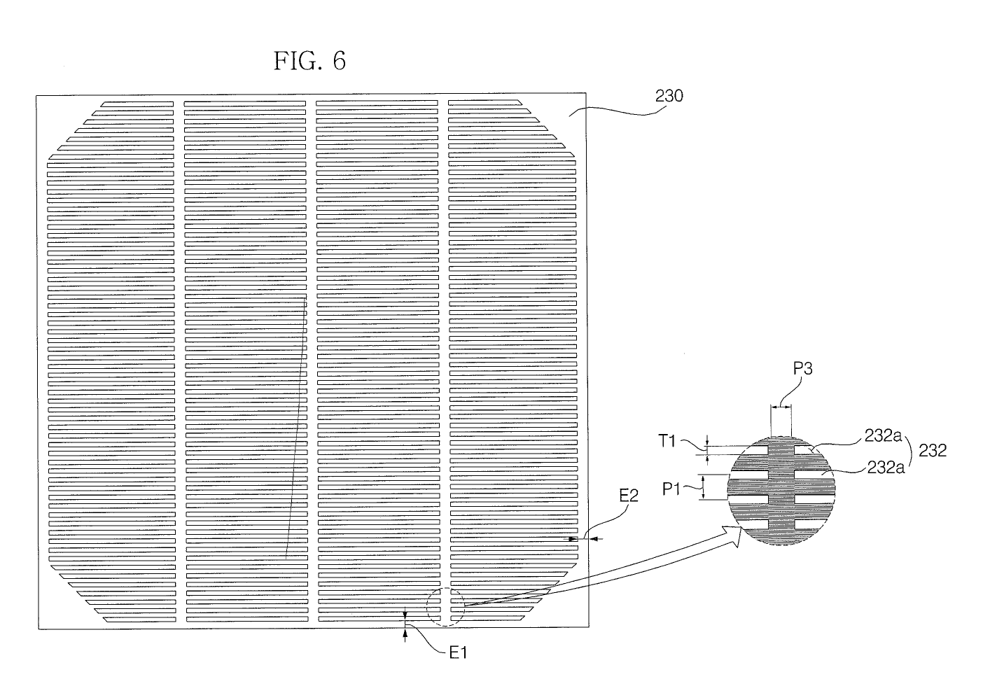

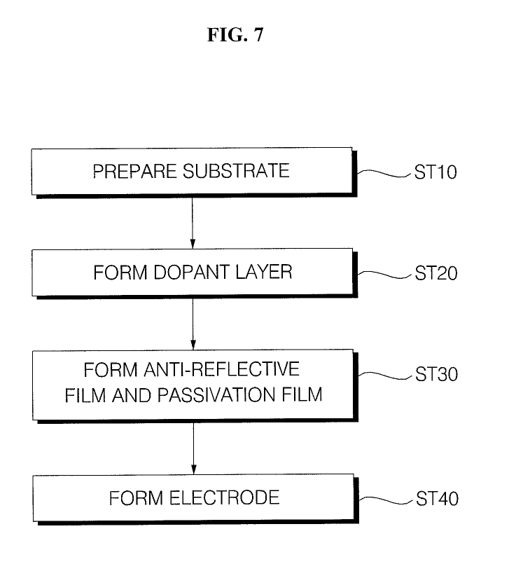

FIG. 7 is a flowchart illustrating a method for manufacturing a solar cell according to an embodiment of the present invention.

Referring to FIG. 7, the method for manufacturing a solar cell according to the illustrated embodiment includes preparing a substrate (ST10), forming dopant layers (ST20), forming an anti-reflective film and a passivation film, and forming electrodes (ST40).

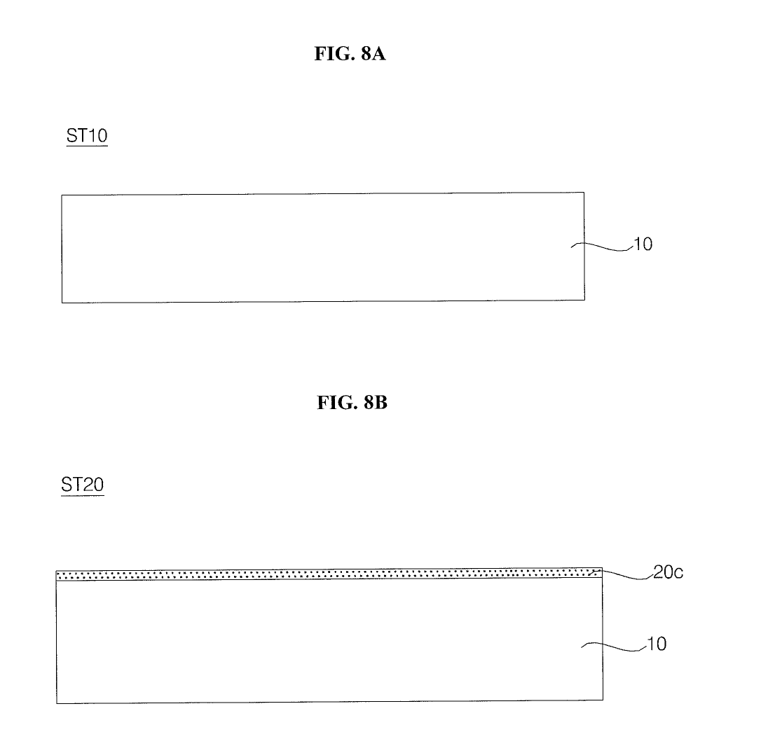

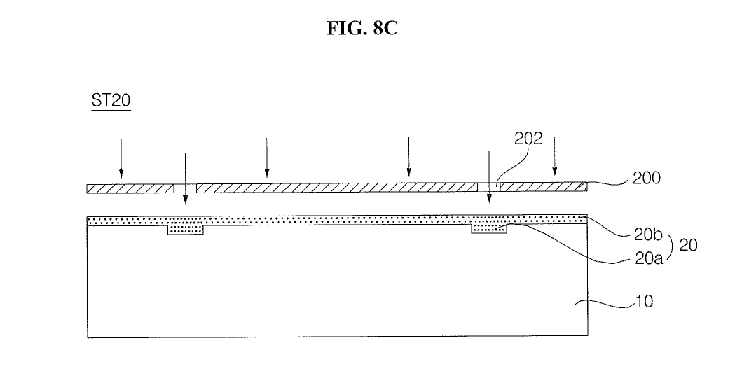

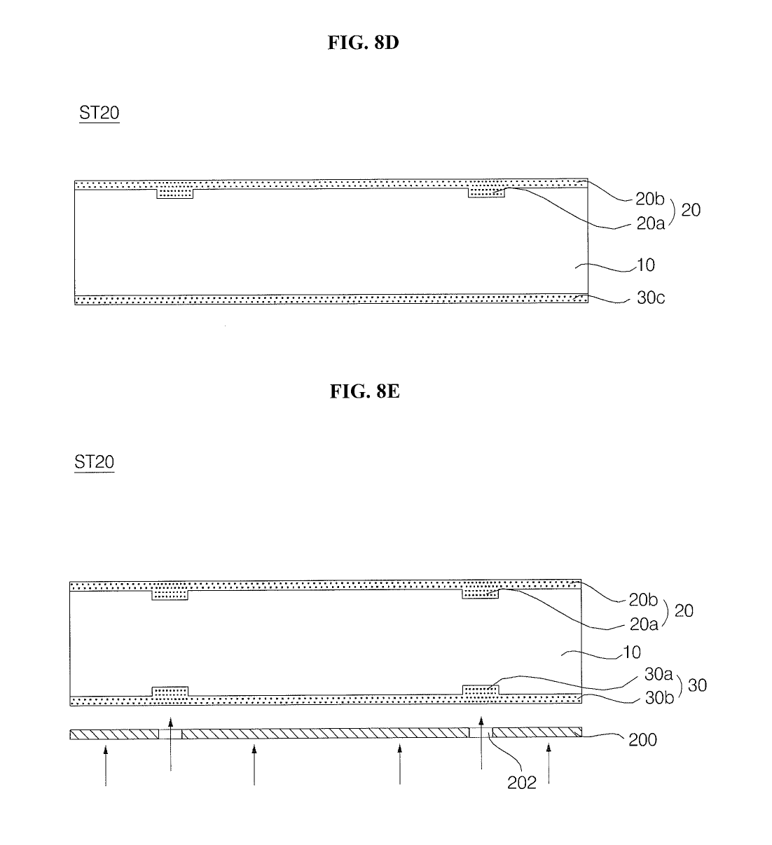

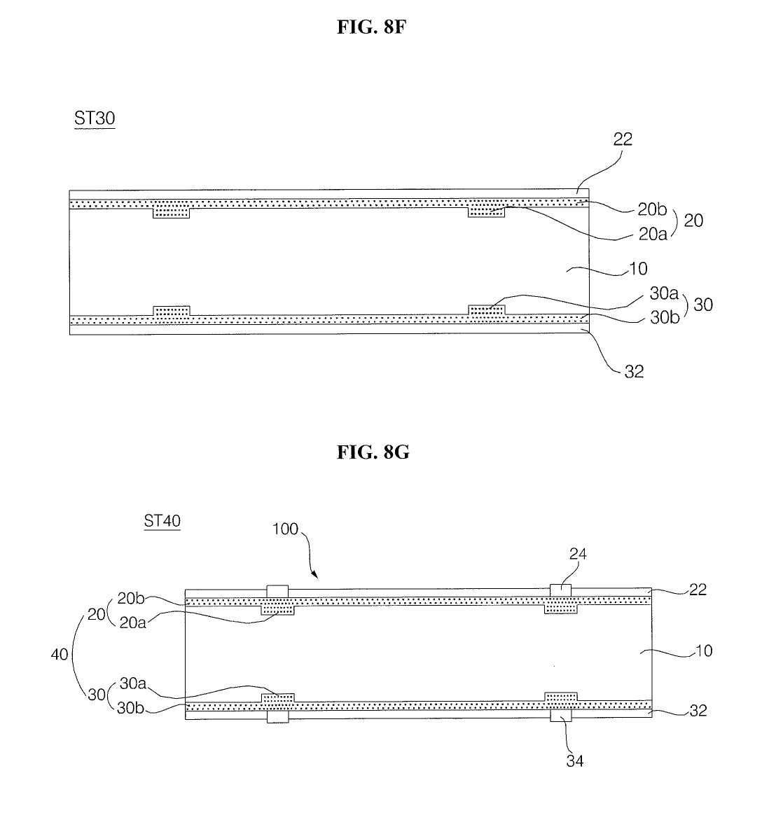

The method will be described in more detail with reference to FIGS. 8A to 8G. FIGS. 8A to 8G are a flowchart illustrating the method for manufacturing a solar cell according to the embodiment of the present invention.

First, as shown in FIG. 8A, in step ST10 of preparing a substrate, a semiconductor substrate 10 having the second conductive dopant is prepared. At this time, the front surface and back surface of the semiconductor substrate 10 may be provided with protrusions and depressions through texturing. As texturing, wet texturing or dry texturing can be used. Wet texturing can be performed by submerging the semiconductor substrate 10 in a solution for texturing. Wet texturing has an advantage of a short process time. Dry texturing is performed by cutting the surface of the semiconductor substrate 10 using a diamond drill or a laser. The dry texturing technique can produce uniform protrusions and depressions. However, it has a long process time and may cause damage to the semiconductor substrate 10. Alternatively, using reactive-ion etching (RIE), only one of the front surface and back surface of the semiconductor substrate 10 may be textured. As described above, texturing of the semiconductor substrate 10 can be performed using various techniques.

In the subsequent step ST20 of forming dopant layers as shown in FIGS. 8B to 8E, the emitter layer 20 and the back surface field layer 30 are formed as the dopant layers. A detailed description thereof is given below.

As shown in FIG. 8B, by performing doping with the first conductive dopant, an emitter formation layer 20c can be formed on the front surface of the semiconductor substrate 10. The emitter formation layer 20c can be formed using various techniques. For example, doping of the first conductive dopant may be performed using a technique such as thermal diffusion and ion implantation to form the emitter formation layer 20c on the front surface of the semiconductor substrate 10.

In thermal diffusion, doping of the first conductive dopant is performed by diffusing a gaseous compound of the first conductive dopant (e.g., BBr3) into the semiconductor substrate 10 which is in a heated state. This technique simplifies the manufacturing process and thus lowers costs. Ion implantation is a technique of implanting the first conductive dopant. Ion implantation can reduce doping in a lateral direction, thereby increasing the degree of integration and facilitating concentration adjustment. In addition, the front surface and back surface of the semiconductor substrate 10 can be doped with different dopants by applying surface doping techniques that allow only a desired surface to be doped.

The emitter formation layer 20c can be formed to have a uniform doping concentration as a whole, and thus have a uniform resistance.

Subsequently, as shown in FIG. 8C, the first conductive dopant is selectively implanted into corresponding portions using the mask 200. The first conductive dopant is implanted into the portions of the mask 200 at which the slits 202 are formed to form the first portions 20a having a relatively high concentration and low resistance. The other portions not doped with the first conductive dopant by the mask 200 configure the second portions 20b.

To perform selective doping with the first conductive dopant, various techniques, e.g. thermal diffusion and ion implantation, can be used. Ion implantation is most often used.

Subsequently, as shown in FIG. 8D, the back surface electric field formation layer 30c is formed by performing doping with the second conductive dopant. In addition, as shown in FIG. 8E, selective doping with the second conductive dopant is performed using the mask 200 to form the back surface field layer 30. The technique of doping with the second conductive dopant in the process shown in FIGS. 8D and 8E is the same as or very similar to that of doping with the first conductive dopant in the process shown in FIGS. 8B and 8C, and therefore a detailed description thereof will be omitted.

While the back surface field layer 30 has been illustrated above as being formed after the emitter layer 20 is formed, the layers can be formed in reverse order. In addition, in the case that ion implantation is used for doping with a dopant, heat treatment for activation of the dopant can be performed after each ion implantation process or all of the ion implantation processes have been completed.

In the subsequent step ST30 of forming an anti-reflective film and a passivation film as shown in FIG. 8F, the anti-reflective film 22 and the passivation film 32 are respectively formed on the front surface and back surface of the semiconductor substrate 10. The anti-reflective film 22 and the passivation film 32 can be formed using one of various techniques such as vacuum deposition, chemical vapor deposition, spin coating, screen printing or spray coating.

In the subsequent step ST40 of forming electrodes as shown in FIG. 8G, the first electrode 24 to contact the first portions 20a of the emitter layer 20 is formed on the front surface of the semiconductor substrate 10, and the second electrode 34 to contact the first portions 30a of the back surface field layer 30 is formed on the back surface of the semiconductor substrate 10.

The first electrodes 24 can be formed by forming openings in the anti-reflective film 22 and applying a technique such as plating or deposition to the openings. In addition, the second electrodes 34 can be formed by forming openings in the passivation film 32 and applying a technique such as plating or deposition to the openings.

Alternatively, the first and second electrodes 24 and 34 can be formed in a shape describe above by applying paste for formation of the first and second electrodes onto the anti-reflective film 22 and the passivation film 32 using a technique such as screen printing and then performing fire through or laser firing contact. In this case, a process of separately forming openings does not need to be performed.

As described above, the first electrodes 24 and/or the second electrodes 34 may include the finger electrodes 44a and the bus bar electrodes 44b. Only the finger electrodes 44a may contact the first portions 40a, or both the finger electrodes 44a and the bus bar electrodes 44b may contact the first portions 40a.

In the illustrated embodiment, the emitter layer 20 and the back surface field layer 30 are formed as the dopant layers, and then the anti-reflective film 22 and the passivation film 32 are formed. Thereafter, the first and second electrodes 24 and 34 are formed. However, embodiments of the present invention are not limited thereto. The emitter layer 20, the back surface field layer 30, the anti-reflective film 22, the passivation film 32, the first electrode 24, and the second electrode 34 can be formed in different orders.

In the illustrated embodiment, the emitter layer 20 and the back surface field layer 30 both have selective structures. However, embodiments of the present invention are not limited thereto. Only one of the emitter layer 20 and the back surface field layer 30 can alternatively have a selective structure.

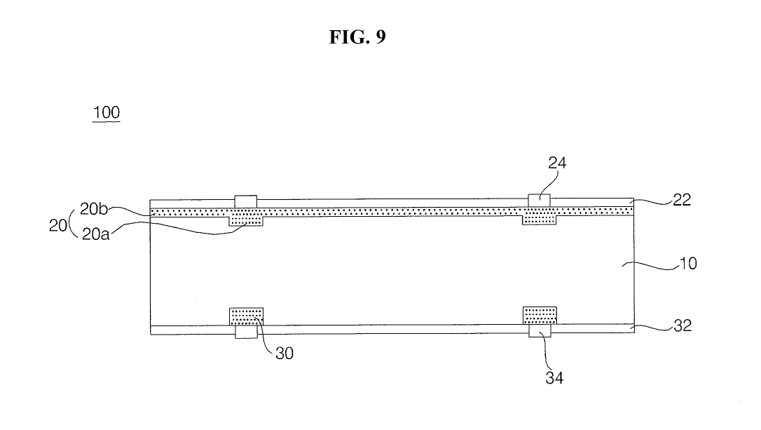

In addition, as shown in FIG. 9, the back surface field layer 30 may be provided with a local back surface field structure. That is, the back surface field layer 30 may be provided only with the first portions 30a which are locally formed only at the portions corresponding to at least one portion of the second electrode 34. Such a back surface field layer 30 may be formed by performing only the process of locally doping with the second conductive dopant (the process corresponding to FIG. 8E) using the mask 200, omitting the process of entirely doping with the second conductive dopant (the process corresponding to FIG. 8D). This is also within the scope of the present invention.

In addition, in the illustrated embodiment, the semiconductor substrate 10 and the back surface field layer include an n-type dopant, and the emitter layer 20 includes a p-type dopant. However, embodiments of the present invention are not limited thereto. The semiconductor substrate 10 and the back surface field layer may alternatively include a p-type dopant, and the emitter layer 20 may include an n-type dopant.

Hereinafter, the present invention will be described in more detail with reference to example experiments. However, these experiments are simply illustrative, and embodiments of the present invention are not limited thereto.

Experiment 1

A plate having a thickness of 1 mm and including graphite was prepared. The plate was irradiated with a femtosecond laser having a wavelength of 780 nm to manufacture a plurality of slits having a width of 0.35 mm and spaced 1.0 mm from each other.

Experiment 2

A plate having a thickness of 1 mm and including graphite was prepared. The plate was irradiated with a picosecond laser having a wavelength of 340 nm, a frequency of 100 kHz and a power of 50 W to manufacture a plurality of slits having a width of 0.35 mm and spaced 1.0 mm from each other.

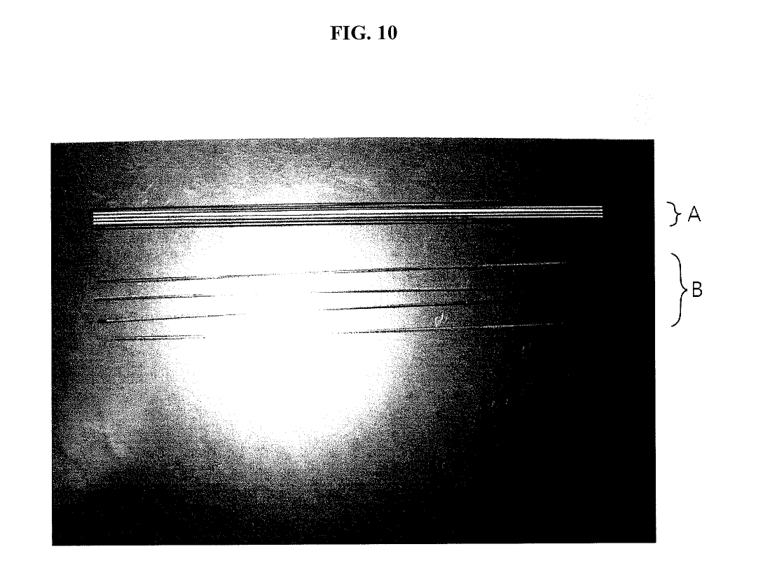

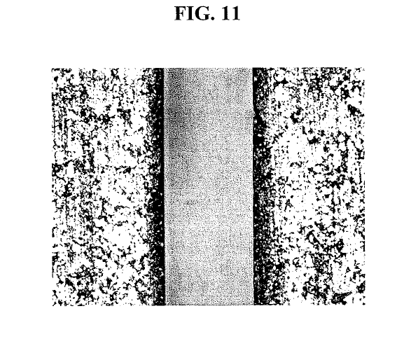

A photo of slits manufactured according to Experiment 1 is shown in FIG. 10. In FIG. 10, the slits were formed at portion A and parts separated from the plate are shown in portion B. Referring to FIG. 10, it can be seen that portions of the plate corresponding to the slits are cleanly removed and the slits are well formed.

A photo of slits manufactured according to Experiment 2 is shown in FIG. 11. Referring to FIG. 11, it can be seen that portions of the substrate corresponding to the slits are cleanly removed and the slits are well formed. In addition, according to Experiment 2, time taken to form the slits could be greatly reduced by applying proper power and frequency, and thereby it was possible to manufacture a mask within two days.

According to the experiments as above, slits of a desired shape can be formed on a mask formed of a nonmetallic material, and manufacturing time can also be reduced.

Although the embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method for manufacturing a mask for a solar cell, the method comprising:
preparing a plate formed of a nonmetallic material; and
irradiating the plate with a laser and forming a plurality of slits.

2. The method according to claim 1, wherein the laser is irradiated along a boundary of each of the plurality of slits to separate portions of the plate corresponding to the plurality of slits from a substrate of the plate.

3. The method according to claim 1, wherein a width of each of the plurality of slits is between about 0.1 mm and about 0.4 mm, and a pitch of neighboring ones of the plurality of slits is between about 0.6 mm and about 1 mm.

4. The method according to claim 1, wherein the laser is a femtosecond laser or a picosecond laser.

5. The method according to claim 1, wherein the laser is a picosecond laser, and
wherein:
a wavelength of the laser is between about 300 nm and about 800 nm;
a frequency of the laser is between about 100 kHz and about 400 kHz; and
a power of the laser is between about 30 W and about 50 W.

6. The method according to claim 1, wherein the mask for the solar cell is used when a dopant layer having a selective structure is formed.

7. The method according to claim 1, wherein a thickness of the plate is about 0.8 mm to about 1.2 mm.

8. The method according to claim 1, wherein the plurality of slits comprise a plurality of first slit portions extending in a first direction and spaced from each other in a second direction crossing the first direction.

9. The method according to claim 8, wherein each of the plurality of first slit portions comprise a plurality of slit portions spaced from each other in the first direction.

10. The method according to claim 9, wherein the plurality of slit portions are spaced with a distance between about 1 mm to about 2 mm from each other in the first direction.

11. The method according to claim 1, wherein the plurality of slits comprise a plurality of first slit portions extending in a first direction, and at least one second slit portion extending in a second direction crossing the first direction and spaced from the plurality of first slit portions.

12. The method according to claim 11, wherein ones of the plurality of first slit portions neighboring the at least one second slit portion are spaced a distance of about 0.5 mm to about 2.0 mm from the at least one second slit portion.

13. A mask for manufacturing a dopant layer, the mask comprising:
a plurality of slits formed of a nonmetallic material, a width each of the plurality of slits being between about 0.1 mm and about 0.4 mm, and a pitch of neighboring ones of the plurality of slits being between about 0.6 mm and about 1 mm.

14. The mask according to claim 13, wherein the plurality of slits comprise a plurality of first slit portions extending in a first direction and spaced from each other in a second direction crossing the first direction.

15. The mask according to claim 14, wherein each of the plurality of first slit portions comprise a plurality of slit portions spaced from each other in the first direction.

16. The mask according to claim 15, wherein the plurality of slit portions are spaced a distance of about 1 mm to about 2 mm from each other in the first direction.

17. The mask according to claim 13, wherein the plurality of slits comprise a plurality of first slit portions extending in a first direction, and at least one second slit portion extending in a second direction crossing the first direction and spaced apart from the plurality of first slit portions.

18. The mask according to claim 13, wherein one of the plurality of first slit portions neighboring the at least one second slit portion is spaced a distance of about 0.5 mm to about 2.0 mm from the at least one second slit portion in a first direction.

19. The mask according to claim 13, wherein the nonmetallic material includes graphite.

20. A method for manufacturing a dopant layer for a solar cell, the method comprising:
preparing a semiconductor substrate;
positioning a mask on the semiconductor substrate; and
doping the semiconductor substrate with a dopant and forming a dopant layer having a selective structure or a local structure,
wherein the mask comprises a plurality of slits formed by irradiating a plate formed of a nonmetallic material with a laser.
